(19) United States
(12) Patent Application Publication
(10) Pub. No.: US 2016/0081201 A1
(43) Pub. Date: Mar. 17, 2016

(54) MULTILAYER ELECTRONIC STRUCTURE WITH INTEGRAL FARADAY SHIELDING

(71) Applicant: Zhuhai Advanced Chip Carriers & Electronic Substrate Solutions Technologies Co. Ltd., Zhuhai (CN)

(72) Inventor: Dror Hurwitz, Zhuhai (CN)

(73) Assignee: Zhuhai Advanced Chip Carriers & Electronic Substrate Solutions Technologies Co. Ltd., Zhuhai (CN)

(21) Appl. No.: 14/937,337

(22) Filed: Nov. 10, 2015

Related U.S. Application Data
(63) Continuation of application No. 13/483,207, filed on May 30, 2012, now abandoned.

(51) Int. Cl. H05K 3/46; H05K 9/00; H05K 3/42

(52) U.S. Cl. CPC H05K 3/4644; H05K 3/429; H05K 9/0024

(57) ABSTRACT

A multilayer electronic support structure including at least one metallic component encapsulated in a dielectric material, and comprising at least one faraday barrier to shield the at least one metallic component from interference from external electromagnetic fields and to prevent electromagnetic emission from the metallic component.

### CROSS REFERENCE TO RELATED APPLICATION

The present application is a continuation of U.S. patent application Ser. No. 13/483,207, entitled “Multilayer Electronic Structure With Integral Faraday Shielding” and filed May 30, 2012. The contents of U.S. Ser. No. 13/483,207 are hereby incorporated by reference herein in their entirety.

### BACKGROUND

1. Field of the Disclosure

The present invention relates to multilayer electronic support structures such as interconnects, including integral Faraday barriers and cages, and methods for their fabrication.

2. Description of the Related Art

Driven by an ever greater demand for miniaturization of ever more complex electronic components, consumer electronics such as computing and telecommunication devices are becoming more integrated. This has created a need for support structures such as IC substrates and IC interposers that have a high density of multiple conductive layers and vias that are electrically insulated from each other by a dielectric material.

The general requirement for such support structures is reliability and appropriate electrical performance, thinness, stiffness, planarity, good heat dissipation and a competitive unit price.

Of the various approaches for achieving these requirements, one widely implemented manufacturing technique that creates interconnecting vias between layers uses lasers to drill holes through the subsequently laid down dielectric substrate through to the latest metal layer for subsequent filling with a metal, usually copper, that is deposited therein by a plating technique. This approach to creating vias is sometimes referred to as ‘drill & fill’, and the vias created thereby may be referred to as ‘drilled & filled vias’.

There are, however, a number of disadvantages with the drilled & filled via approach:

Since each via is required to be separately drilled, the throughput rate is limited, and the costs of fabricating sophisticated, multi-via IC substrates and interposers becomes prohibitive.

In large arrays it is difficult to produce a high density of high quality vias having different sizes and shapes in close proximity to each other by the drill & fill methodology.

Furthermore, laser drilled vias have rough side walls and taper inwards through the thickness of the dielectric material. This tapering reduces the effective diameter of the via. It may also adversely affect the electrical contact to the previous conductive metal layer especially at ultra small via diameters, thereby causing reliability issues.

The side walls are particularly rough where the dielectric being drilled is a composite material comprising glass or ceramic fibers in a polymer matrix, and this roughness may create additional stray inductances.

The filling process of the drilled via holes is usually achieved by copper electroplating. This metal deposition technique may result in dimpling, where a small crater appears at the top of the via. Alternatively, overfill may result, where a via channel is filled with more copper than it can hold, and a domed upper surface that protrudes over the surrounding material is created. Both dimpling and overfill tend to create difficulties when subsequently stacking vias one on top of the other, as required when fabricating high-density substrates and interposers.

Large via channels are difficult to fill uniformly, especially when they are in proximity to smaller vias within the same interconnecting layer of the interposer or IC substrate design.

Laser drilling is best for creating round via channels. Although slot shaped via channels may be fabricated by laser milling, nevertheless, the range of geometries that may be fabricated by ‘drill & fill’ is somewhat limited. Fabrication of vias by drill & fill is expensive and it is difficult to evenly and consistently fill the via channels created thereby with copper using the relatively, cost-effective electroplating process.

Although the range of acceptable sizes and reliability is improving over time, the disadvantages described hereinabove are intrinsic to the drill & fill technology and are expected to limit the range of possible via sizes.

An alternative solution that overcomes many of the disadvantages of the drill & fill approach, is to fabricate vias by depositing copper or other metal into a pattern created in a photoresist, using a technology otherwise known as ‘pattern plating’.

In pattern plating, a seed layer is first deposited. Then a layer of photoresist is laid down over the seed layer and subsequently exposed to create a pattern, which is selectively removed to leave trenches that expose the seed layer. Via posts are created by depositing copper into the photoresist trenches. The remaining photoresist is then removed, the seed layer is etched away, and a dielectric material that is typically a polymer impregnated glass fiber mat, is laminated thereover and therearound to encase the via posts. Various techniques and processes, such as grinding, polishing and chemical mechanical polishing may then be used to thin and planarize the resulting surface, removing part of the dielectric material and exposing the top of the via posts, allowing building up the next metal layer. Subsequent layers of metal conductors and via posts may be deposited there onto by repeating the process to build up a desired multilayer structure.

In an alternative but closely linked technology, known hereinafter as ‘panel plating’, a continuous layer of metal or alloy is deposited onto a substrate. A layer of photoresist is laid on top of the continuous layer, and a pattern is developed therein. The pattern of developed photoresist is stripped away, selectively exposing the metal thereunder, which may then be etched away. The undeveloped photoresist protects the underlying metal from being etched away, and leaves a pattern of upstanding features and vias.

After stripping away the undeveloped photoresist, a dielectric material, such as a polymer impregnated glass fiber mat, may be laminated around and over the upstanding copper features and/or via posts.

The via layers created by pattern plating or panel plating methodologies described above are typically known as via post layers and feature layers. Copper is a preferred metal for both layers.

It will be appreciated that the general thrust of the microelectronic evolution is directed towards fabricating ever smaller, thinner and lighter and more powerful products having high reliability. The use of thick, cored interconnects, prevents ultra-thin products being attainable. To create ever higher densities of structures in the interconnect IC substrate or interposer, ever more layers of ever smaller connections are required. Indeed, sometimes it is desirable to stack components on top of each other.

If plated, laminated structures are deposited on a copper or other appropriate sacrificial substrate, the substrate may be etched away leaving free standing, coreless laminar structures. Further layers may be deposited on the side previously adhered to the sacrificial substrate, thereby enabling a two sided build up, which minimizes warping and aids the attaining of planarity.

One flexible technology for fabricating high density interconnects is to build up pattern or panel plated multilayer structures consisting of metal vias or features in a dielectric matrix. The metal may be copper and the dielectric may be a fiber reinforced polymer, typically a polymer with a high glass transition temperature (T_{g}) is used, such as polyimide, for example. These interconnects may be cored or coreless, and may include cavities for stacking components. They may have odd or even numbers of layers. Enabling technology is described in previous patents issued to Amitec-Advanced Multilayer Interconnect Technologies Ltd.

For example, U.S. Pat. No. 7,682,972 to Hurwitz et al. titled “Advanced multilayer coreless support structures and method for their fabrication” describes a method of fabricating a free standing membrane including a via array in a dielectric, for use as a precursor in the construction of superior electronic support structures. The method includes the steps of fabricating a membrane of conductive vias in a dielectric surround on a sacrificial carrier, and detaching the membrane from the sacrificial carrier to form a free standing laminated array. An electronic substrate based on such a free standing membrane may be formed by thinning and planarizing the laminated array, followed by terminating the vias. This publication is incorporated herein by reference in its entirety.

U.S. Pat. No. 7,669,320 to Hurwitz et al. titled “Coreless cavity substrates for chip packaging and their fabrication” describes a method for fabricating an IC support for supporting a first IC die connected in series with a second IC die; the IC support comprising a stack of alternating layers of copper features and vias in insulating surround. The first IC die is bondable onto the IC support, and the second IC die is bondable within a cavity inside the IC support, wherein the cavity is formed by etching away a copper base and selectively etching away built up copper. This publication is incorporated herein by reference in its entirety.

U.S. Pat. No. 7,635,641 to Hurwitz et al. titled “integrated circuit support structures and their fabrication” describes a method of fabricating an electronic substrate comprising the steps of: (A) selecting a first base layer; (B) depositing a first adhesive etchant resistant barrier layer onto the first base layer; (C) building up a first half stack of alternating conductive layers and insulating layers, the conductive layers being interconnected by vias through the insulating layers; (D) applying a second base layer onto the first half stack; (E) applying a protective coating of photoresist to the second base layer; (F) etching away the first base layer; (G) removing the protective coating of photoresist; (H) removing the first adhesive etchant resistant barrier layer; (I) building up a second half stack of alternating conductive layers and insulating layers, the conductive layers being interconnected by vias through the insulating layers, wherein the second half stack has a substantially symmetrical lay up to the first half stack; (J) applying an insulating layer onto the second hall stack of alternating conductive layers and insulating layers, (K) removing the second base layer, and (L) terminating the substrate by exposing ends of vias on outer surfaces of the stack and applying terminations thereto. This publication is incorporated herein by reference in its entirety.

### BRIEF SUMMARY

A first aspect of the invention is directed to providing a multilayer electronic support structure including at least one functional metallic component encapsulated in a dielectric material, and further comprising at least one faraday barrier within the dielectric material for shielding the at least one functional metallic component from interference from external electromagnetic fields and for preventing electromagnetic emission from the metallic component.

In some embodiments, the at least one functional metallic component comprises a signal carrier.

In some embodiments, the at least one functional metallic component comprises copper.

In some embodiments, the at least one functional metallic component is situated in a via layer further comprising connecting vias linking adjacent feature layers above and below.

In some embodiments, the at least one functional metallic component further comprises an underlying layer that is selected from the group consisting of a sputtered seed layer, an electroplated metal layer and an electroplated metal layer deposited over a sputtered or electroless plated seed layer.

In some embodiments, the at least one functional metallic component further comprises an overlying layer that is selected from the group consisting of a sputtered seed layer, an electroplated metal layer and an electroplated metal layer deposited over a sputtered or electroless plated seed layer.

In some embodiments, the at least one functional metallic component comprises circuitry.

In some embodiments, the at least one faraday barrier comprises: an upper metallic layer above the at least one metallic component, and a lower metallic layer below the at least one metallic component.

In some embodiments, the at least one faraday barrier further comprises: elements on each side of the at least one metallic component that are coupled by rows of via posts to the upper and lower metallic layers to provide a faraday cage.

In some embodiments, the rows of via posts are continuous.

In some embodiments, the rows of via posts are discontinuous.

In some embodiments, the at least one faraday barrier comprises copper.

Typically, the dielectric material comprises a polymer.

In some embodiments, the dielectric material further comprises ceramic or glass.

In some embodiments, the polymer comprises polyimide, epoxy, Bismaleimide, Triazine and blends thereof.

In some embodiments, the dielectric material further comprises glass fibers.

In some embodiments, the dielectric material further comprises ceramic particle fillers.

A second aspect is directed to a process of fabricating the multilayer electronic structure of claim 1, comprising the steps of:
(a) Obtaining a substrate including an upper layer comprising a continuous metal ground plane;
(b) Applying a first layer of photoresist over the continuous metal ground plane;
(c) Developing the first layer of photoresist with a pattern comprising a pair of lower rows of metal vias;
(d) Pattern plating the pair of lower rows of metal vias into the first layer of photoresist;
(e) Stripping away the first layer of photoresist;
(f) Laminating a first layer of dielectric material over the pair of lower rows of metal vias;
(g) Thin away the first layer of dielectric material to expose ends of the pair of lower rows of metal vias;
(h) Deposit a first metal seed layer over the first layer of dielectric material;
(i) Apply a second layer of photoresist over the first metal seed layer;
(j) Expose and develop a pattern including a metallic element and adjacent faraday barriers on both sides in the second layer of photoresist;
(k) Cofabricate the metallic element and adjacent faraday barriers by pattern plating;
(l) Strip away the second layer of photoresist;
(m) Apply a third layer of photoresist;
(n) Expose and develop a third pattern comprising upper rows of via posts in the third layer of photoresist;
(o) Pattern plate the upper rows of via posts into the exposed and developed pattern;
(p) Strip away the third layer of photoresist;
(q) Remove the seed layer;
(r) Laminate a layer of dielectric material over the upper rows of via posts;
(s) Thin away the dielectric material expose ends of the upper rows of via posts, and
(t) Deposit an upper layer of metal over the exposed ends.

In some embodiments, the upper layer of metal comprises a metal seed layer.

In some embodiments, the upper layer of metal further comprises a layer of metal deposited by electroplating.

In some embodiments stages (h) to (s) are repeated to build up more complex shielded structures.

The term microns or μm refers to micrometers, or 10⁻⁶ m.

### BRIEF DESCRIPTION OF THE DRAWINGS

For a better understanding of the invention and to show how it may be carried into effect, reference will now be made, purely by way of example, to the accompanying drawings.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention; the description taken with the drawings making apparent to those skilled in the art how the several forms of the invention may be embodied in practice. In the accompanying drawings:

FIG. 1 is a simplified section through a multilayer electronic support structure of the prior art;

FIG. 2 is a schematic illustration of a cross-section through a first component protected by a faraday cage;

FIG. 3 is a schematic illustration of a cross-section through a three layer circuit protected by a faraday cage;

FIG. 4 is a schematic illustration of a of a cross-section through a three layer conducting feature protected by a faraday cage;

FIG. 5 is a flowchart showing one manufacturing technique for fabricating the structure of FIG. 2, and

FIG. 6 is a flowchart showing a second manufacturing technique.

Like reference numbers and designations in the various drawings indicated like elements.

### DETAILED DESCRIPTION

In the description hereinbelow, support structures consisting of metal vias in a dielectric matrix, particularly, copper via posts in a polymer matrix, such as polyimide, epoxy or BT (Bismaleimide/Triazine) or their blends, reinforced with glass fibers are considered.

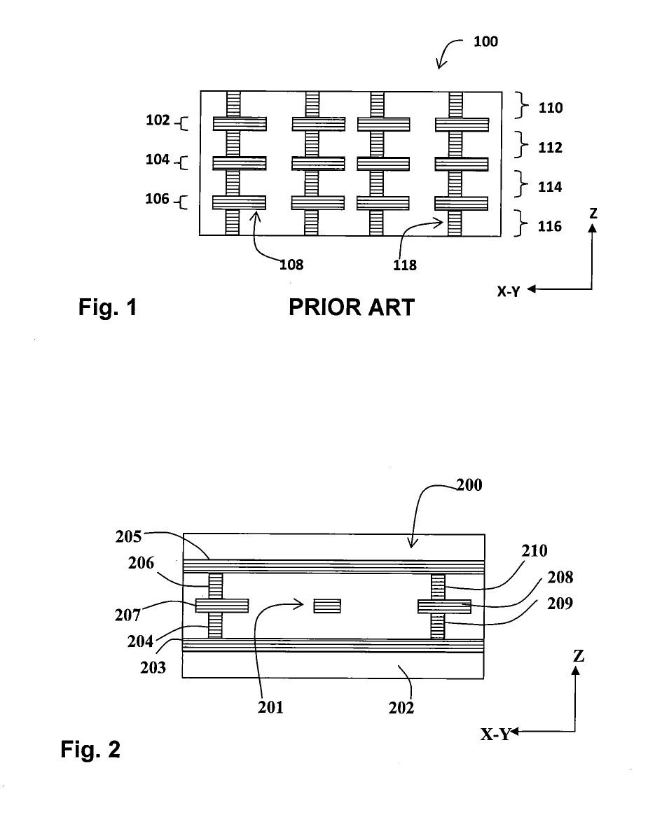

With reference to FIG. 1, a simplified section through a multilayer electronic support structure of the prior art is shown. Multilayer electronic support structures 100 of the prior art include functional layers 102, 104, 106 of components or features 108 separated by layers of dielectric 110, 112, 114, 116, which insulate the individual layers. Vias 118 through the dielectric layer provide electrical connection between the adjacent functional or feature layers. Thus the feature layers 102, 104, 106 include features 108 generally laid out within the layer, in the X-Y plane, and vias 118 that conduct current across the dielectric layers 110, 112, 114, 116. Vias 118 are designed to have minimal inductance and are sufficiently separated to have minimum capacitances therebetween.

In general, vias and features in an interconnect or other substrate are separated by the dielectric to prevent interference. It will, however, be appreciated that sometimes vias and other conductive or functional structures within an interconnect or other substrate as described hereinabove, may be sensitive to Radio Frequency (RF) or other Electro-Magnetic Interference (RFI/EMI) which may result in electrical signal attenuation and/or noise.

As well established, electromagnetic shielding may be accomplished by protecting such conductors, vias and structures with a conducting barrier shield, generally known as a Faraday barrier. A Faraday cage is a three dimensional structure created from Faraday barriers that provides protection from induced currents and inductances of components or conduits enclosed therewithin.

With reference to FIG. 2, a structure having a central conductor 201, encapsulated within the dielectric material 202 of the substrate, is electromagnetically shielded by a lower conductive plate 203, an upper conductive plate 205, left and right side pads 207, 208 on the same layer as the central conductor 201, and conductor vias 204, 206, 209, 210 connecting the pads 207, 208 to the lower and upper conductive plates 203, 205.

As will be appreciated by persons of the art, the Faraday cage 200 created around the conductor 201, does not need to be surrounded completely on all sides and the surrounding via conductors 204, 206, 209, 210 do not need to be completely continuous structures, but may be separate via posts separated from each other while electrically connected through pads 207 and 208. Thus the via conductors 204, 206, 209, 210 may be fabricated using via post methodology, such as described in U.S. Pat. No. 7,682,972, U.S. Pat. No. 7,669,320 and U.S. Pat. No. 7,635,641 to Hurwitz et al, and incorporated herein by reference. Alternatively, taking advantage of the possibility of electroplating continuous elongated vias, the via conductors 204, 206, 209, 210 may be continuous linear vias, a cross section through which being shown.

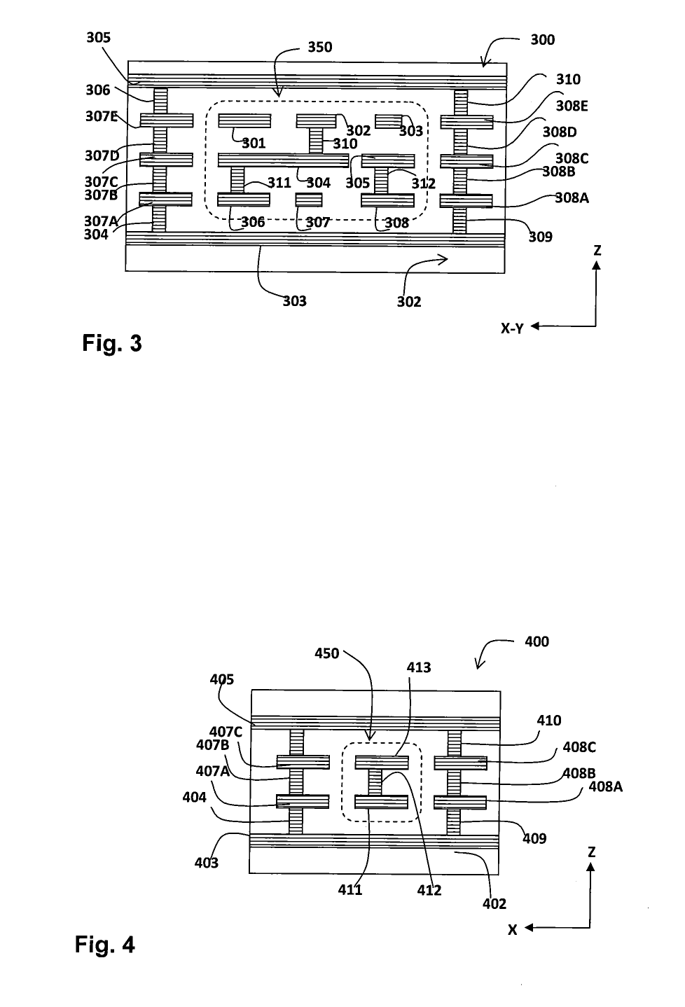

With reference to FIG. 3, a structure similar to the one presented in FIG. 2 is shown. In this substrate structure various conductors 301, 302, 303, 304, 305, 306, 307, 308 form a 3 layer sub circuit interconnected by via structures 310, 311, 312 all embedded within a dielectric material 302, and form circuitry 350 which may be one or several electrical circuits within a given area of the substrate, that may be surrounded with via conductors 307B, 307D, 308B, 308D, and their related pads 307A, 307C, 307E, 308A, 308C, 308E, and bottom and top metal planes 303, 305 to form a surrounding Faraday cage 300 that provides RFI/EMI protection for the circuit 350 thus enclosed.

It will be appreciated by persons skilled in the art, that the embodiments of FIGS. 2 and 3 are schematic simplified embodiments, provided by way of example only, and the circuitry RFI/EMI protected by a faraday cage is not limited to a specific number of layers or to a certain circuitry location within the substrate.

Faraday shielding provided by a conductor via and its associated pads and by top and bottom metal planes, may be used to separate a certain section within a substrate from other sections, for example, to separate an analog from a digital section, an RF circuit from a digital circuit to prevent noise, or to isolate the entire substrate from radiation.

The shielded metallic component may comprise signal carriers, for example.

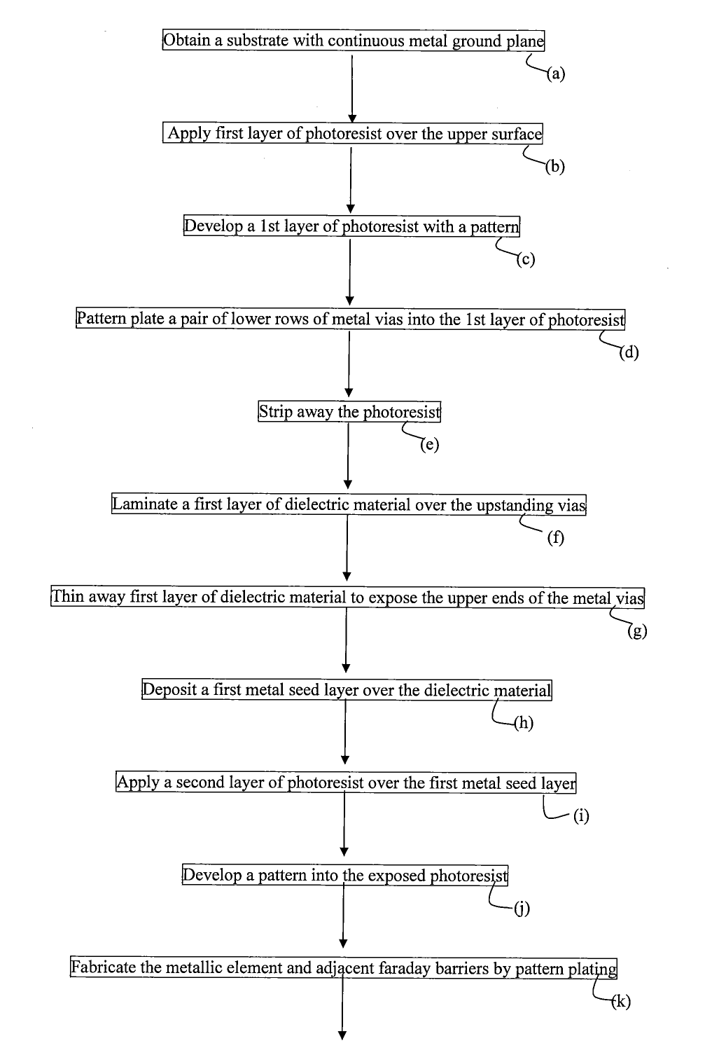

With reference to FIG. 4, a bottom conductor line 411 and a top conductor line 413 may be interconnected by a via conductor 412 to generate an RFI/EMI shielded conducting feature 410 embedded in dielectric material 418 and surrounded by a faraday cage 450 represented by top and bottom metal planes 403 and 405 for top and bottom RFI/EMI protection and on the sides by via conductors 407B, and their interconnecting pads 407A, 407C, by via conductors 408B and their interconnecting pads 408A, 408C for further RFI/EMI side protection.

The ‘via conductor’ 412 shown in FIG. 4 provides significant improvement over the feature 201 shown in FIG. 2, since the RFI/EMI protected feature 410 of interconnecting bottom and top pads 411, 413 has a significantly lower DC resistance when compared to the metal conductor 201 of FIG. 2, thereby providing additional flexibility to the electrical designer in distribution and transfer of the necessary shielded electrical current while operating sensitive drivers within the Integrated Circuit (IC).

It may be noted that the bottom conductor pads 407A, 411, 408A may be very thin conductive layers such as seed layers having a thickness of up to about a micron, and deposited by sputtering or by electroless plating. The bottom conductor pads 407A, 411, 408A only serve the purpose of allowing the via conductors 407B, 412, 408B to be pattern electroplated together with other conductors and via posts (not shown) in the same layers but at other location of the substrate, as described in the pattern plating via post process flow of U.S. Pat. No. 7,682,972, U.S. Pat. No. 7,669,320 and U.S. Pat. No. 7,635,641 to Hurwitz et al.

It may be further noted that the top interconnected conductor pads 407C, 413, 408C need only be thick enough to serve as a seed layer to allow other conductors or vias (not shown) to be build in the same or subsequent layers, elsewhere in the substrate, for example by using the pattern plating process as described in U.S. Pat. No. 7,682,972, U.S. Pat. No. 7,669,320 and U.S. Pat. No. 7,635,641 to Hurwitz et al. Thus the top interconnected conductor pads 407C, 413, 408C may be up to about 1 micron thick and may be deposited by sputtering or electroless plating.

It may also be noted that all the pad pairs 407A/407C, 408A/408C and 412 may have dimensions as close as possible to the corresponding ‘via conductors’ 407B, 408B and 412.

In the various embodiments, the upper and lower rows of via posts may be discontinuous via posts separated from each other by dielectric and may be substantially cylindrical like the vias fabricable by drill & fill technology. Using pattern or panel plating, the via posts need not be round and may be square or rectangular, for example, and may be continuous strips, extending in parallel to a data-line.

In some embodiments, the metallic component and the surrounding faraday cage may be fabricated from copper.

The dielectric material may be a polymer such as polyimide, epoxy, Bismaleimide, Triazine and blends thereof.

Typically, the dielectric material further comprises ceramic or glass, such as glass reinforcement fibers and ceramic particle fillers.

The dielectric material may be a pre-preg consisting of a woven fiber mat impregnated with a resin, for example.

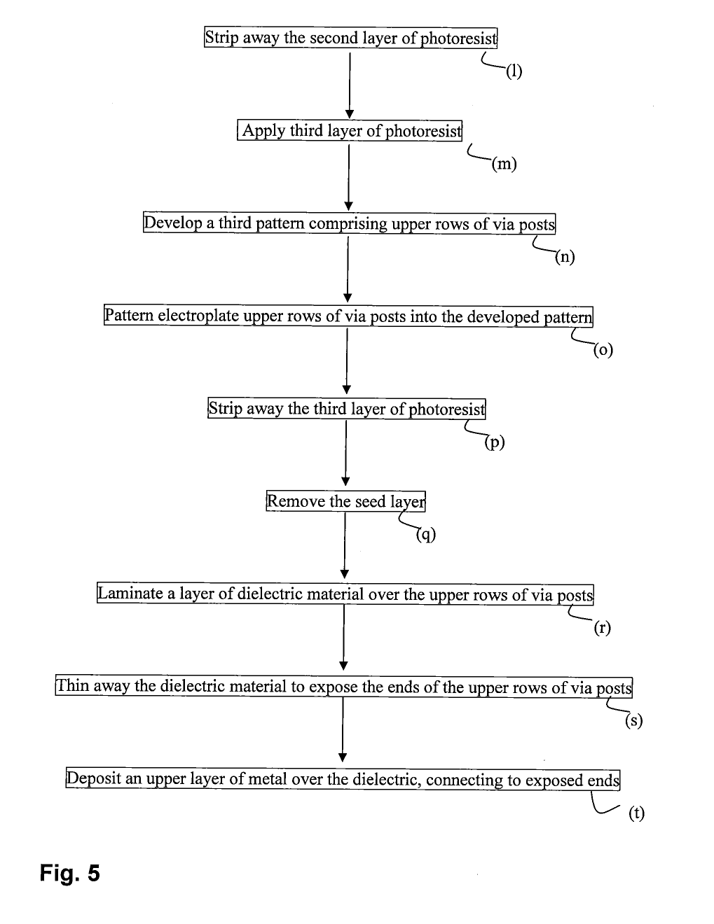

Referring to FIG. 5, one method of fabricating a multilayer electronic structure including a faraday cage, such as that shown in FIG. 2, comprises the following steps: A substrate with an upper surface comprising a continuous metal ground plane is obtained—step (a). A first layer of photoresist is applied over the continuous ground plane—step (b), and the first layer of photoresist is developed with a pattern comprising a pair of lower rows of copper vias—step (c). Lower rows of metal vias are then pattern plated into the first layer of photoresist—step (d). The photoresist is stripped away—step (e) and a first layer of dielectric material is laminated typically by applying a pre-preg and curing—step (f). The first layer of dielectric material is thinned away to expose ends of the lower rows of metal vias—step (g). Various techniques and processes may be used for thinning, such as grinding, polishing and chemical mechanical polishing, to remove part of the dielectric material and to expose the top of the via posts, allowing building up the next metal layer. A first metal seed layer is then deposited over the dielectric—step (h). This is typically copper and is generally 0.5 micron to 1.5 micron thick, and may be deposited by electroless plating or by sputtering, for example. To increase its adhesion, an adhesion layer of titanium or tantalum may be first deposited, also by sputtering. The adhesion layer is typically 0.04 micron to 0.1 micron thick. A second layer of photoresist is applied over the first metal seed layer—step (i) and a pattern is exposed and developed in the second layer of photoresist including the metallic element and adjacent faraday barriers on both sides wherein the adjacent faraday barriers are coupled to the rows of metal vias step (j). The metallic element and the adjacent faraday barriers are cofabricated by pattern plating into the exposed and developed photoresist—step (k). The second layer of photoresist is stripped away—step (l), A third layer of photoresist is applied—step (m) and a third pattern comprising upper rows of via posts is exposed and developed in the third layer of photoresist—step (n). The upper rows of via posts are pattern electroplated into the exposed and developed pattern—step (o). The third layer of photoresist is stripped away—step (p). The seed layer is removed—step (q), optionally, it is etched away with a wet etch of ammonium hydroxide or copper chloride, for example, and a layer of dielectric material is laminated over the upper rows of via posts—step (s). The dielectric material is thinned away to expose the ends of the upper rows of via posts—step (t). Mechanical polishing or grinding, chemical polishing or chemical mechanical polishing (CMP) may be used, and an upper layer of metal is deposited over the dielectric, connected to the exposed ends—step (t). The upper layer may be a seed layer, typically copper, deposited by sputtering or by electroless plating. In some embodiments, the upper layer of metal further comprises a thicker layer of metal deposited by electroplating.

The individual via and feature layers from which the component to be protected and the surrounding faraday cage are typically part of a larger layout (not shown) of structures and vias in the substrate. Each double layer of features or pads followed by a via layer is generally deposited by repeating steps (h) to (t).

Typically, the seed layers and the plated layers may be fabricated from copper. The seed layer may be 0.5 to 1.5 microns thick. To further aid adherence of the seed layer to the underlying dielectric, a very thin layer, typically 0.04 microns to 0.1 microns of an adhesion metal, such as titanium, tantalum, tungsten, chromium or mixtures thereof, may first be applied.

The upper and lower rows of via posts may be continuous, consisting of extensive strips of metal, or may consist of individual via posts.

Stages (h) to (s) may be repeated to build up more complex shielded structures such as those shown in FIGS. 3 and 4, for example.

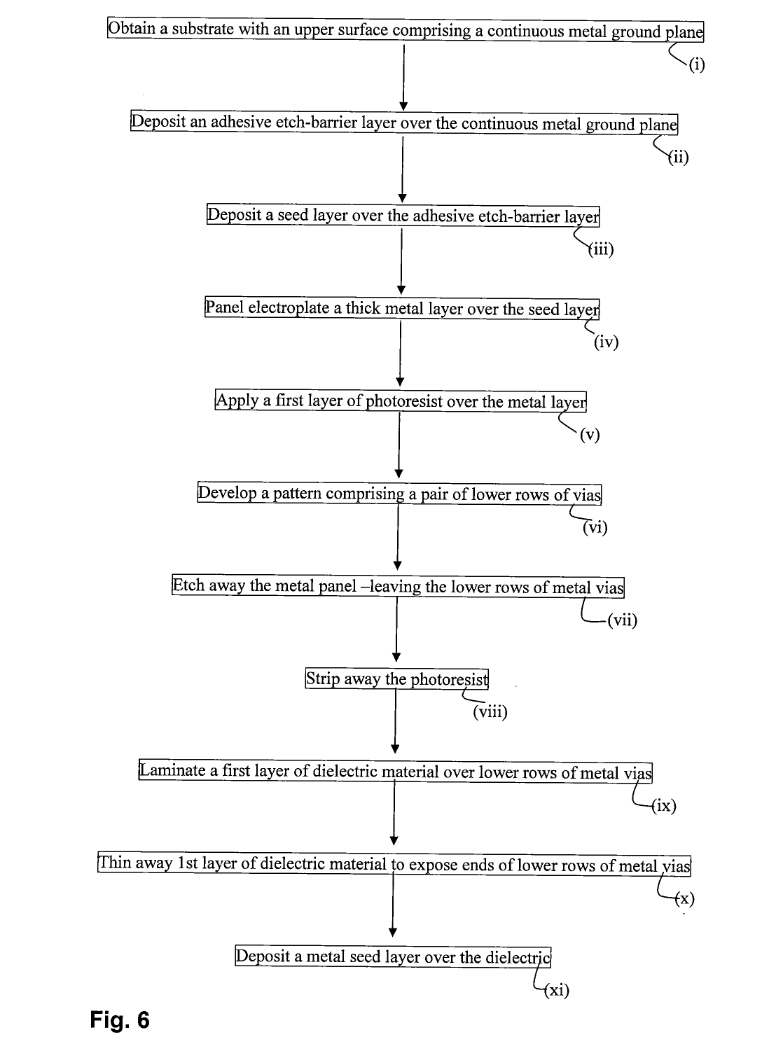

With reference to FIG. 6, a second method is now described. A substrate with an upper surface comprising a continuous metal ground plane is obtained—step (i). An etch-barrier layer is deposited over the continuous metal ground plane—step (ii). The etch-barrier layer may be fabricated from Tantalum, Tungsten, Chromium, Titanium, a Titanium-Tungsten combination, a Titanium-Tantalum combination, Nickel, Gold, a Nickel layer followed by a Gold layer, a gold layer followed by a Nickel layer, Tin, Lead, a Tin layer followed by a Lead layer, Tin-Lead alloy, and Tin Silver alloy and may be applied by a Physical Vapor deposition process. Typically, the etch barrier layer is a metal such as titanium Ti, chromium Cr, tantalum Ta, tungsten W and combinations thereof, for example.

A seed layer is deposited over the etch-barrier layer—step (iii). The seed layer may be sputtered or electroless plated from copper, for example. A thick metal layer is now panel electroplated thereover—step (iv). A first layer of photoresist is applied over the metal layer—step (v), and developed with a pattern comprising a pair of lower rows of via posts—step (vi) and other features elsewhere in the layer. The metal panel is now etched away—step (vi), leaving the lower rows of metal via posts and other features. An etchant such as ammonium hydroxide or copper chloride may be used.

The photoresist is stripped away—step (vii) and a first layer of dielectric material is laminated over the lower rows of metal via posts and other features—step (viii). The first layer of dielectric material is thinned away to expose ends of the lower rows of metal via posts—step (ix). Various techniques and processes may be used for thinning, such as grinding, polishing and chemical mechanical polishing to remove part of the dielectric material and to expose the top of the via posts, allowing building up the next metal layer.

A first metal seed layer is deposited over the dielectric—step (x). This is typically copper and may be deposited by electroless plating or by sputtering, for example. The seed layer may be 0.5 to 1.5 microns thick. Over the seed layer, a thick layer of metal, typically copper, may be pattern or panel plated. To further aid adherence of the seed layer to the underlying dielectric, a very thin layer, typically 0.04 microns to 0.1 microns of an adhesion metal, such as titanium, tantalum, tungsten, chromium or mixtures thereof, may first be applied.

The subsequent layers may be deposited by pattern plating or by panel plating, and more complex structures, including circuits and components, protected my faraday barriers, such as those shown in FIGS. 3 and 4 may be built up.

The etch-barrier layer is then removed using a specific etchant that does not attack the copper. For example, Ti, W, Ta may be removed using a plasma etch comprising CF₄/O₂ or CF₄/Ar to remove selectively leaving Cu. Alternatively, a 1-3% HF solution is very effective in removing Ti, leaving copper. If barrier layer is nickel, a selective nickel stripper as known, may be used.

Thus persons skilled in the art will appreciate that the present invention is not limited to what has been particularly shown and described hereinabove. Rather the scope of the present invention is defined by the appended claims and includes both combinations and sub combinations of the various features described hereinabove as well as variations and modifications thereof, which would occur to persons skilled in the art upon reading the foregoing description.

In the claims, the word “comprise”, and variations thereof such as “comprises”, “comprising” and the like indicate that the components listed are included, but not generally to the exclusion of other components.

Thus persons skilled in the art will appreciate that the present invention is not limited to what has been particularly shown and described hereinabove. Rather the scope of the present invention is defined by the appended claims and includes both combinations and sub combinations of the various features described hereinabove as well as variations and modifications thereof, which would occur to persons skilled in the art upon reading the foregoing description.

In the claims, the word “comprise”, and variations thereof such as “comprises”, “comprising” and the like indicate that the components listed are included, but not generally to the exclusion of other components.

1. A method of fabricating a multilayer electronic structure, comprising the steps of:
(a) Obtaining a substrate including an upper layer comprising a continuous metal ground plane;
(b) Applying a first layer of photoresist over the continuous metal ground plane;
(c) Developing the first layer of photoresist with a pattern comprising a pair of lower rows of metal vias;
(d) Pattern plating the pair of lower rows of metal vias into the first layer of photoresist;
(e) Stripping away the first layer of photoresist;
(f) Laminating a first layer of dielectric material over the pair of lower rows of metal vias;
(g) Thin away the first layer of dielectric material to expose ends of the pair of lower rows of metal vias;
(h) Deposit a first metal seed layer over the first layer of dielectric material;
(i) Apply a second layer of photoresist over the first metal seed layer;
(j) Expose and develop a pattern including a metallic element, adjacent faraday barriers on both sides in the second layer of photoresist and conductive pads aligned with the lower rows of metal vias;
(k) Cofabricate the metallic element, adjacent faraday barriers and conductive pad by pattern plating by electroplating pure copper into the pattern;
(l) Strip away the second layer of photoresist;
(m) Apply a third layer of photoresist;
(n) Expose and develop a third pattern comprising upper rows of via posts in the third layer of photoresist aligned with the conductive pads;
(o) Pattern plate the upper rows of via posts into the exposed and developed pattern;
(p) Strip away the third layer of photoresist;
(q) Remove the seed layer;
(r) Laminate a layer of dielectric material over the upper rows of via posts;
(s) Thin away the dielectric material expose ends of the upper rows of via posts, and
(t) Deposit an upper layer of metal over the exposed ends.

2. The method of claim 1 wherein the upper layer of metal comprises a metal seed layer.

3. The method of claim 1 wherein the upper layer of metal further comprises a layer of metal deposited by electroplating.

4. The method of claim 3, wherein stages (h) to (s) are repeated to build up more complex shielded structures.

5. A method of fabricating a multilayer electronic structure, comprising the steps of:
providing a lower metal layer having a surface;
forming on the surface of the lower metal layer a second layer, including the steps of
depositing a first amount photoresist,
patterning into the first amount of photoresist a lower set of vias,
electroplating the lower set of vias,
applying dielectric whereby the ends of the lower set of vias are exposed;
forming on the second layer a third layer having a first and second pad separated from at least one functional metallic component by dielectric;
forming on the third layer a fourth layer, including the steps of depositing a second amount photoresist,
patterning into the second amount of photoresist an upper set of vias,
electroplating the upper set of vias,
applying dielectric whereby the ends of the upper set of vias are exposed; and
depositing an upper metal layer on the fourth layer.

6. The method of claim 5 wherein the at least one functional metallic component is a signal carrier.

7. The method of claim 5 wherein the at least one functional metallic component includes a first conductor and a second conductor electrically interconnected by a connecting via.

8. The method of claim 7 wherein the at least one functional metallic component further includes an underlying layer that is selected from the group consisting of a sputtered seed layer, an electroplated metal layer and an electroplated metal layer deposited over a sputtered or electroless plated seed layer.

9. The method of claim 7 wherein the at least one functional metallic component further includes an overlying layer that is selected from the group consisting of a sputtered seed layer, an electroplated metal layer and an electroplated metal layer deposited over a sputtered or electroless plated seed layer.

10. The method of claim 7 wherein the at least one functional metallic component includes circuitry.

11. The method of claim 7 wherein at least one of the lower set of vias and upper set of vias are interconnected to form a continuous via formation.

12. The method of claim 7 wherein the lower set of vias and upper set of vias are discontinuous.

13. The method of claim 5 wherein the dielectric is a polymer.

14. The method of claim 13 wherein the dielectric further includes one of ceramic and glass.

15. The method of claim 13 wherein the polymer includes at least one of polymide, epoxy, Bismaleidmide, Triazine and blends thereof.

16. The method of claim 14 wherein the dielectric further comprises glass fibers.

17. The method of claim 14 wherein the dielectric further comprises ceramic particle fillers.

18. The method of claim 5 wherein the lower metal layer is copper.

19. The method of claim 5 wherein the upper metal layer is copper.
